(19) United States
(12) Patent Application Publication
(10) Pub. No.: US 2005/0221020 A1
(43) Pub. Date: Oct. 6, 2005

(54) Method of improving the wafer to wafer uniformity and defectivity of a deposited dielectric film

(75) Inventor: Noriaki Fukiage, Hartsdale, NY (US)

Correspondence Address: PILLSBURY WINTHROP SHAW PITTMAN, LLP, P.O. BOX 10500, MCLEAN, VA, 22102, US

(73) Assignee: Tokyo Electron Limited, Tokyo (JP)

(21) Appl. No.: 10/812,354

(22) Filed: Mar. 30, 2004

(51) Int. Cl. H05H 1/24; C23C 16/00

(52) U.S. Cl. 427/569; 118/723 I; 118/723 IR

(57) ABSTRACT

A method and apparatus are included that provide an improved deposition process for a Tunable Etch Resistant ARC (TERA) layer with improved wafer to wafer uniformity and reduced particle contamination. More specifically, the processing chamber is seasoned to reduce the number of contaminant particles generated in the chamber during the deposition of the TERA layer and improve wafer to wafer uniformity. The apparatus includes a chamber having an upper electrode at least one RF source, a substrate holder, and a showerhead for providing multiple precursors and process gasses.

### CROSS-REFERENCE TO RELATED APPLICATIONS

This application is related to co-pending U.S. patent application Ser. No. 10/644,958, entitled “Method and Apparatus For Depositing Materials With Tunable Optical Properties And Etching Characteristics”, filed on Aug. 21, 2003; co-pending U.S. patent application Ser. No. 10/702,048, entitled “Method for Improving Photoresist Film Profile”, filed on Nov. 6, 2003; and co-pending U.S. patent application Ser. No. 10/702,043, entitled “Method of Improving Post-Develop Photoresist Profile on a Deposited Dielectric Film”, filed on Nov. 6, 2003. The entire contents of these applications are herein incorporated by reference in their entirety.

### FIELD OF THE INVENTION

The invention relates to using a plasma-enhanced chemical vapor deposition (PECVD) system to deposit thin-film, and more specifically, to depositing films having improved wafer to wafer uniformity and reduced contaminants.

### BACKGROUND OF THE INVENTION

Integrated circuit and device fabrication requires deposition of electronic materials on substrates. Material deposition is often accomplished by plasma-enhanced chemical vapor deposition (PECVD), wherein a substrate (wafer) is placed in a reaction chamber and exposed to an ambient of reactive gases. The gases react on the wafer surface to form the film. Often, film forming reactions also occur on the surfaces of the reaction chamber, resulting in a build-up of material or reaction byproducts on the chamber walls, exhaust line, gas injection and dispersion hardware, etc. The materials and byproducts deposited on the reactor surfaces may dislodge from the surfaces during the deposition process and settle on the wafer in the form of particulates. The introduction of particles during the fabrication process can reduce device yield.

In addition to serving as a source of particulate defects, material build-up on reactor walls may also impact the performance and repeatability of the deposition process. The film may alter the heat transfer characteristics of the reactor, thereby changing the effective temperature of the film forming reaction. This can alter the kinetics of the reactions at the substrate, which can adversely affect the properties of the material that is being deposited. In addition, film deposits on the reactor walls may serve as nucleation sites for undesirable or parasitic reaction pathways. This further affects the chemical reactions at the wafer surface, and hence may alter the properties of the deposited film.

### SUMMARY OF THE INVENTION

The invention relates to a method for operating a plasma enhanced chemical vapor deposition (PECVD) system, where the method includes performing a chamber seasoning process, where the chamber seasoning process comprises a chamber cleaning process or a chamber pre-coating process, or both; the chamber cleaning process when employed, using a fluorine-containing gas, an oxygen-containing gas, or an inert gas, or a combination of two or more thereof. and the chamber pre-coating process when employed, using a silicon-containing precursor, carbon-containing precursor, or an inert gas, or a combination of two or more thereof.

In addition, the method can include performing a post-process chamber cleaning process, where the post-process chamber cleaning process uses a fluorine-containing gas, an oxygen-containing gas, or an inert gas, or a combination thereof.

### BRIEF DESCRIPTION OF THE DRAWINGS

In the drawings:

FIG. 1 illustrates a simplified block diagram for a PECVD system in accordance with an embodiment of the invention;

FIG. 2A illustrates a simplified block diagram for a semiconductor processing system in accordance with an embodiment of the invention;

FIG. 2B shows a simplified wafer flow diagram through the semiconductor processing system illustrated FIG. 2A;

FIG. 3A illustrates a simplified block diagram for another semiconductor processing system in accordance with an embodiment of the invention;

FIG. 3B shows a simplified wafer flow diagram through the semiconductor processing system illustrated FIG. 3A;

FIG. 4 shows a simplified flow diagram of a procedure for reducing the amount of particles deposited on a substrate in accordance with an embodiment of the invention;

FIG. 5 illustrates a table of data for exemplary processes that were performed to verify the methods of the invention;

FIG. 6 illustrates a graph of the foreign material (FM) data for processes that were performed to verify the methods of the invention;

FIG. 7 illustrates a graph of the thickness data for processes that were performed to verify the methods of the invention;

FIG. 8A shows an exemplary view of particle contamination on a substrate using an unprocessed chamber; and

FIG. 8B shows an exemplary view of particle contamination on a substrate in accordance with an embodiment of the invention.

### DETAILED DESCRIPTION OF EMBODIMENTS OF THE INVENTION

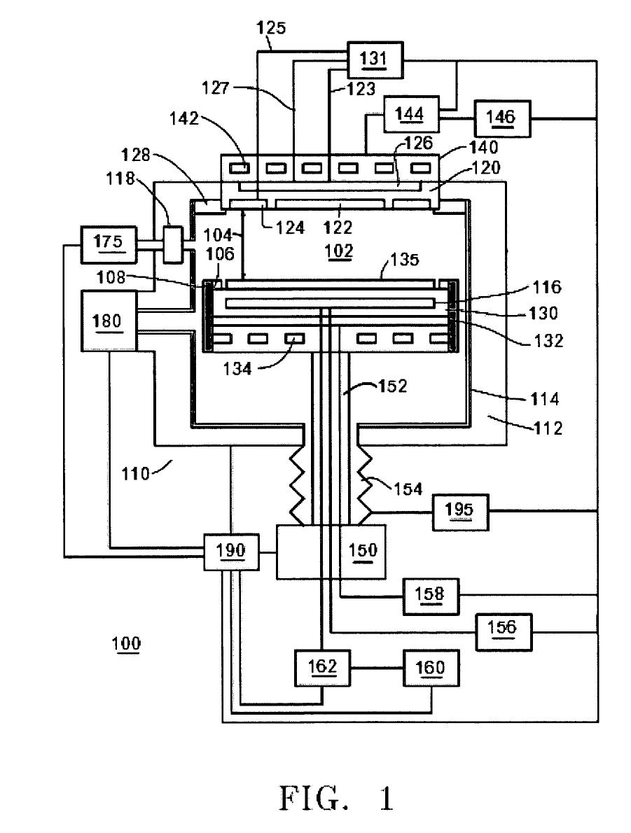

FIG. 1 illustrates a simplified block diagram for a PECVD system in accordance with an embodiment of the invention. In the illustrated embodiment, PECVD system 100 comprises processing chamber 110, upper electrode 140 as part of a capacitively coupled plasma source, shower plate assembly 120, substrate holder 130 for supporting substrate 135, pressure control system 180, and controller 190.

In one embodiment, PECVD system 100 can comprise a remote plasma system 175 that can be coupled to the processing chamber 110 using a valve 178. In another embodiment, a remote plasma system and valve are not required. The remote plasma system 175 can be used for chamber cleaning.

In one embodiment, PECVD system 100 can comprise a pressure control system 180 that can be coupled to the processing chamber 110. For example, the pressure control system 180 can comprise a throttle valve (not shown) and a turbomolecular pump (TMP) (not shown) and can provide a controlled pressure in processing chamber 110. In alternate embodiments, the pressure control system can comprise a dry pump. For example, the chamber pressure can range from approximately 0.1 mTorr to approximately 100 Torr. Alternatively, the chamber pressure can range from approximately 0.1 Torr to approximately 20 Torr.

Processing chamber 110 can facilitate the formation of plasma in process space 102. PECVD system 100 can be configured to process substrates of any size, such as 200 mm substrates, 300 mm substrates, or larger substrates. Alternately, the PECVD system 100 can operate by generating plasma in one or more processing chambers.

PECVD system 100 comprises a shower plate assembly 120 coupled to the processing chamber 110. Shower plate assembly is mounted opposite the substrate holder 130. Shower plate assembly 120 comprises a center region 122, an edge region 124, and a sub region 126. Shield ring 128 can be used to couple shower plate assembly 120 to processing chamber 110.

Center region 122 is coupled to gas supply system 131 by a first process gas line 123. Edge region 124 is coupled to gas supply system 131 by a second process gas line 125. Sub region 126 is coupled to gas supply system 131 by a third process gas line 127. Alternately, other configurations are possible.

Gas supply system 131 provides a first process gas to the center region 122, a second process gas to the edge region 124, and a third process gas to the sub region 126. The gas chemistries and flow rates can be individually controlled to these regions. Alternately, the center region and the edge region can be coupled together as a single primary region, and gas supply system can provide the first process gas and/or the second process gas to the primary region. In alternate embodiments, any of the regions can be coupled together and the gas supply system can provide one or more process gasses as appropriate.

The gas supply system 131 can comprise at least one vaporizer (not shown) for providing precursors. Alternately, a vaporizer is not required. In an alternate embodiment, a bubbling system can be used.

PECVD system 100 comprises an upper electrode 140 that can be coupled to shower plate assembly 120 and coupled to the processing chamber 110. Upper electrode 140 can comprise temperature control elements 142. Upper electrode 140 can be coupled to a first RF source 146 using a first match network 144. Alternately, a separate match network is not required.

The first RF source 146 provides a TRF signal to the upper electrode, and the first RF source 146 can operate in a frequency range from approximately 0.1 MHz. to approximately 200 MHz. The TRF signal can be in the frequency range from approximately 1 MHz. to approximately 100 MHz, or alternatively in the frequency range from approximately 2 MHz. to approximately 60 MHz. The first RF source can operate in a power range from approximately 0 watts to approximately 10000 watts, or alternatively the first RF source operates in a power range from approximately 0 watts to approximately 5000 watts.

Upper electrode 140 and RF source 146 are parts of a capacitively coupled plasma source. The capacitively couple plasma source may be replaced with or augmented by other types of plasma sources, such as an inductively coupled plasma (ICP) source, a transformer-coupled plasma (TCP) source, a microwave powered plasma source, an electron cyclotron resonance (ECR) plasma source, a Helicon wave plasma source, and a surface wave plasma source. As is well known in the art, upper electrode 140 may be eliminated or reconfigured in the various suitable plasma sources.

Substrate 135 can be, for example, transferred into and out of processing chamber 110 through a slot valve (not shown) and chamber feed-through (not shown) via robotic substrate transfer system (not shown), and it can be received by substrate holder 130 and mechanically translated by devices coupled thereto. Once substrate 135 is received from substrate transfer system, substrate 135 can be raised and/or lowered using a translation device 150 that can be coupled to substrate holder 130 by a coupling assembly 152.

Substrate 135 can be affixed to the substrate holder 130 via an electrostatic clamping system. For example, an electrostatic clamping system (ESC) can comprise an electrode 117 and an ESC supply 156. Clamping voltages that can range from approximately −2000 V to approximately +2000 V, for example, can be provided to the clamping electrode. Alternatively, the clamping voltage can range from approximately −1000 V to approximately +1000 V. In alternate embodiments, an ESC system and supply is not required.

Substrate holder 130 can comprise lift pins (not shown) for lowering and/or raising a substrate to and/or from the surface of the substrate holder. In alternate embodiments, different lifting means can be provided in substrate holder 130. In alternate embodiments, gas can, for example, be delivered to the backside of substrate 135 via a backside gas system to improve the gas-gap thermal conductance between substrate 135 and substrate holder 130.

A temperature control system can also be provided. Such a system can be utilized when temperature control of the substrate holder is required at elevated or reduced temperatures. For example, a heating element 132, such as resistive heating elements, or thermo-electric heaters/coolers can be included, and substrate holder 130 can further include a heat exchange system 134. Heating element 132 can be coupled to heater supply 158. Heat exchange system 134 can include a re-circulating coolant flow means that receives heat from substrate holder 130 and transfers heat to a heat exchanger system (not shown), or when heating, transfers heat from the heat exchanger system.

Also, electrode 116 can be coupled to a second RF source 160 using a second match network 162. Alternately, a match network is not required.

The second RF source 160 provides a bottom RF signal (BRF) to the lower electrode 116, and the second RF source 160 can operate in a frequency range from approximately 0.1 MHz. to approximately 200 MHz. The BRF signal can be in the frequency range from approximately 0.2 MHz. to approximately 30 MHz, or alternatively, in the frequency range from approximately 0.3 MHz. to approximately 15 MHz. The second RF source can operate in a power range from approximately 0.0 watts to approximately 1000 watts, or alternatively, the second RF source can operate in a power range from approximately 0.0 watts to approximately 500 watts. In various embodiments, the lower electrode 116 may not be used, or may be the sole source of plasma within the chamber, or may augment any additional plasma source.

PECVD system 100 can further comprise a translation device 150 that can be coupled by a bellows 154 to the processing chamber 110. Also, coupling assembly 152 can couple translation device 150 to the substrate holder 130. Bellows 154 is configured to seal the vertical translation device from the atmosphere outside the processing chamber 110.

Translation device 150 allows a variable gap 104 to be established between the shower plate assembly 120 and the substrate 135. The gap can range from approximately 1 mm to approximately 200 mm, and alternatively, the gap can range from approximately 2 mm to approximately 80 mm. The gap can remain fixed or the gap can be changed during a deposition and cleaning process.

Additionally, substrate holder 130 can further comprise a focus ring 106 and ceramic cover 108. Alternately, a focus ring 106 and/or ceramic cover 108 are not required.

At least one chamber wall 112 can comprise a coating 114 to protect the wall. For example, the coating 114 can comprise a ceramic material. In an alternate embodiment, a coating is not required. Furthermore, a ceramic shield (not shown) can be used within processing chamber 110. In addition, the temperature control system can be used to control the chamber wall temperature. For example, ports can be provided in the chamber wall for controlling temperature. Chamber wall temperature can be maintained relatively constant while a process is being performed in the chamber.

Also, the temperature control system can be used to control the temperature of the upper electrode. Temperature control elements 142 can be used to control the upper electrode temperature. Upper electrode temperature can be maintained relatively constant while a process is being performed in the chamber.

Furthermore, PECVD system 100 can also comprise a purging system 195 that can be used for controlling contamination.

In an alternate embodiment, processing chamber 110 can, for example, further comprise a monitoring port (not shown). A monitoring port can, for example, permit optical monitoring of process space 102.

PECVD system 100 also comprises a controller 190. Controller 190 can be coupled to chamber 110, shower plate assembly 120, substrate holder 130, gas supply system 131, upper electrode 140, first RF match 144, first RF source 146, translation device 150, ESC supply 156, heater supply 158, second RF match 162, second RF source 160, purging system 195, remote plasma device 175, and pressure control system 180. The controller can be configured to provide control data to these components and receive data such as process data from these components. For example, controller 190 can comprise a microprocessor, a memory, and a digital I/O port capable of generating control voltages sufficient to communicate and activate inputs to the processing system 100 as well as monitor outputs from the PECVD system 100. Moreover, the controller 190 can exchange information with system components. Also, a program stored in the memory can be utilized to control the aforementioned components of a PECVD system 100 according to a process recipe. In addition, controller 190 can be configured to analyze the process data, to compare the process data with target process data, and to use the comparison to change a process and/or control the deposition tool. Also, the controller can be configured to analyze the process data, to compare the process data with historical process data, and to use the comparison to predict, prevent, and/or declare a fault.

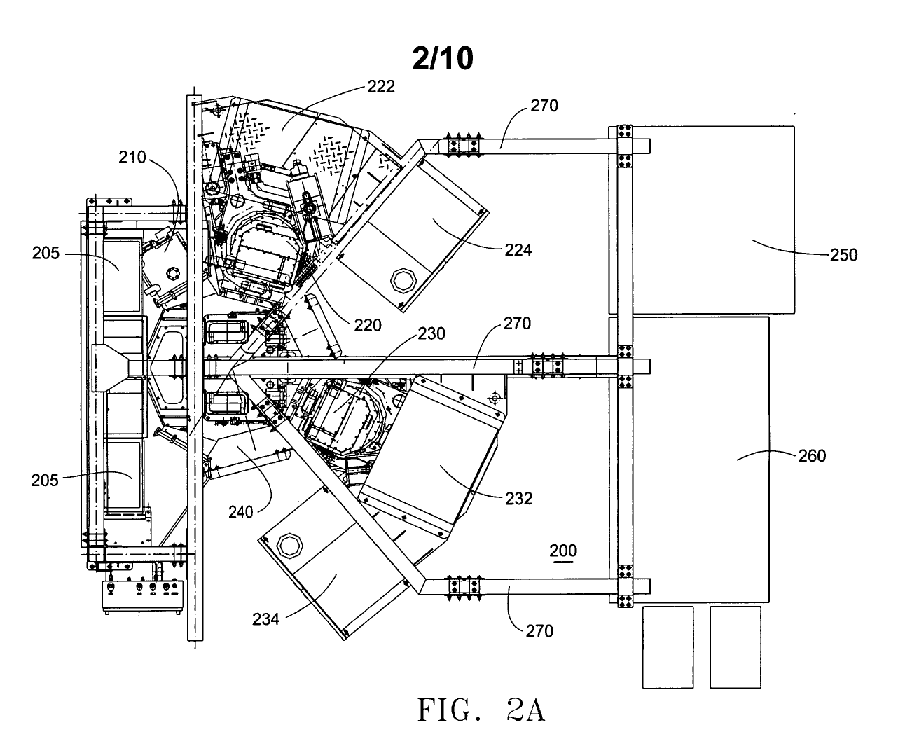

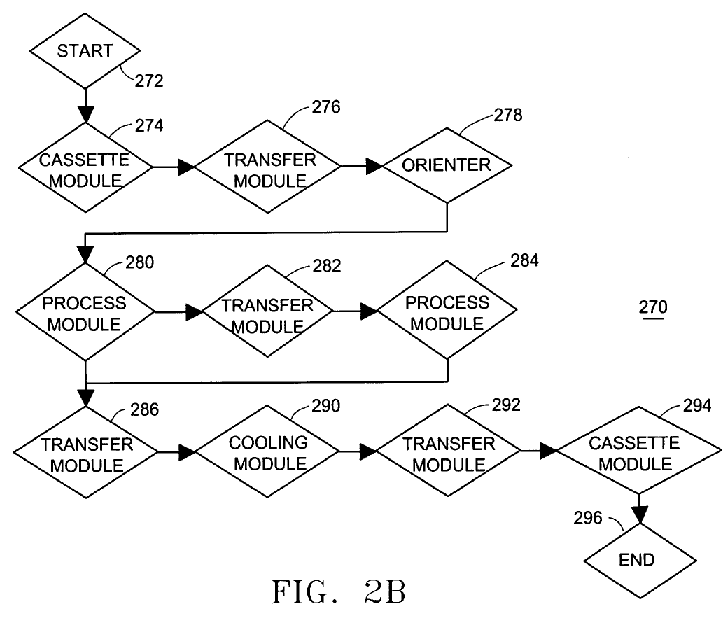

FIG. 2A illustrates a simplified block diagram for a semiconductor processing system in accordance with an embodiment of the invention. In the illustrated embodiment, a semiconductor processing system 200 for processing 200 mm or 300 mm wafers is shown. For example, the semiconductor processing system can be a Unity system from Tokyo Electron Limited (TEL).

Semiconductor processing system 200 can comprise a plurality of cassette modules 205, at least one cooling module 210, a plurality of processing modules (220, 230), a plurality of gas boxes (222, 232), a plurality of liquid delivery systems (224, 234), a transfer module 240, an RF assembly 250, a control assembly 260, and a holding assembly 270.

RF assembly 250 can be coupled to the plurality of processing modules (220, 230). Control assembly 260 can be coupled to and used to control the various components of the semiconductor processing system 200. Holding assembly 270 can be coupled to and used to hold one or more of the various components of the semiconductor processing system 200.

In the illustrated embodiment, two cassette modules 205 are shown, one temperature control module 210 is shown, two processing modules (220, 230) are shown, two gas boxes (222, 232) are shown, two liquid delivery systems (224, 234) are shown, one transfer module 240 is shown, one RF assembly 250 is shown, one control assembly 260 is shown, and one holding assembly 270 is shown, but this is not required for the invention. In alternate embodiments, different configurations can be used, and the processing system can comprise additional components not shown in FIG. 2A.

In the illustrated embodiment, each of cassette modules 205 can hold a plurality of wafers. The cassette modules can be moved and positioned so that one cassette module can be coupled to a transfer port of the transfer module 240 at one time. A transfer mechanism (not shown) can be used to transfer a wafer between the cassette module 205 and the transfer module 240. The wafer can be transferred to an alignment assembly (not shown) in the transfer module 240. The alignment assembly can be used to center and adjust the position of the wafer relative to the notch in the wafer.

In the illustrated embodiment, temperature control module 210 can comprise temperature control elements (not shown) that can be used to control the temperature of a wafer before or after a process is performed. For example, the temperature control module 210 can be a cooling module. The temperature control module 210 can be coupled to a transfer port of the transfer module 240. A transfer mechanism (not shown) can be used to transfer a wafer between the temperature control module 210 and the transfer module 240. For example, a wafer can be transferred to the temperature control module 210 to be cooled after a process has been performed.

In the illustrated embodiment, each of the processing modules (220, 230) can comprise at least one processing chamber (not shown) that can be used to process a wafer. For example, one or more of the processing modules (220, 230) can comprise a plasma enhanced deposition module as shown in FIG. 2A. Alternately, one or more of the processing modules (220, 230) can comprise a chemical vapor deposition (CVD) module, a physical vapor deposition (PVD, iPVD) module, a atomic layer deposition (ALD) module, an etch module, a photoresist coating module, a patterning module, a development module, a thermal processing module, curing module, and/or combinations thereof.

As shown in FIG. 2A, the processing modules (220, 230) can be coupled to different transfer ports of the transfer module 240. A transfer mechanism (not shown) can be used to transfer a wafer between a processing module and the transfer module. For example, a wafer can be transferred to a first processing module where a first process is performed and then transferred to a second processing module where a second process is performed. In addition, a wafer can be processed using only one of the processing modules (220, 230).

As shown in FIG. 2A, gas box 222 is shown coupled to processing module 220, and gas box 232 is shown coupled to processing module 230. For example, gas box 222 can provide processing gasses to processing module 220, and gas box 232 can provide processing gasses to processing module 230.

In addition, liquid delivery system 224 is shown coupled to processing module 220, and liquid delivery system 234 is shown coupled to processing module 230. For example, liquid delivery system 224 can provide processing liquids to processing module 220, and liquid delivery system 234 can provide processing liquids to processing module 230.

FIG. 2B shows a simplified wafer flow diagram through the semiconductor processing system illustrated FIG. 2A. In the illustrated embodiment, an exemplary process flow 270 is shown. The process flow 270 can start in 272, and in 274, one or more cassette modules can be coupled to a processing system. In 276, a wafer can be moved from a cassette module into the transfer module, and in 278, the wafer can be centered and/or aligned using an alignment assembly in the transfer module. In 280, the wafer can be transferred into a processing module and processed. In 286, the processed wafer can be moved back into the transfer module; in 290, the processed wafer can be moved into the cooling module; in 292, the processed wafer can be moved back into the transfer module; and in 294 the processed wafer can be moved into the cassette module; and the process flow can end in 296.

In another exemplary process flow, the processed wafer can be moved in 282 from a process module into the transfer module; and in 284, the processed wafer can be moved into another processing module where another process is performed. In 286, the processed wafer can be moved back into the transfer module and the process flow can continue as shown in FIG. 2B. In alternate process flows, other process modules may be included, and different process flows can be used. For example, an integrated metrology module (IMM) may be coupled to the transfer module and/or a processing module, and measurements can be made using an IMM module before and/or after performing a process.

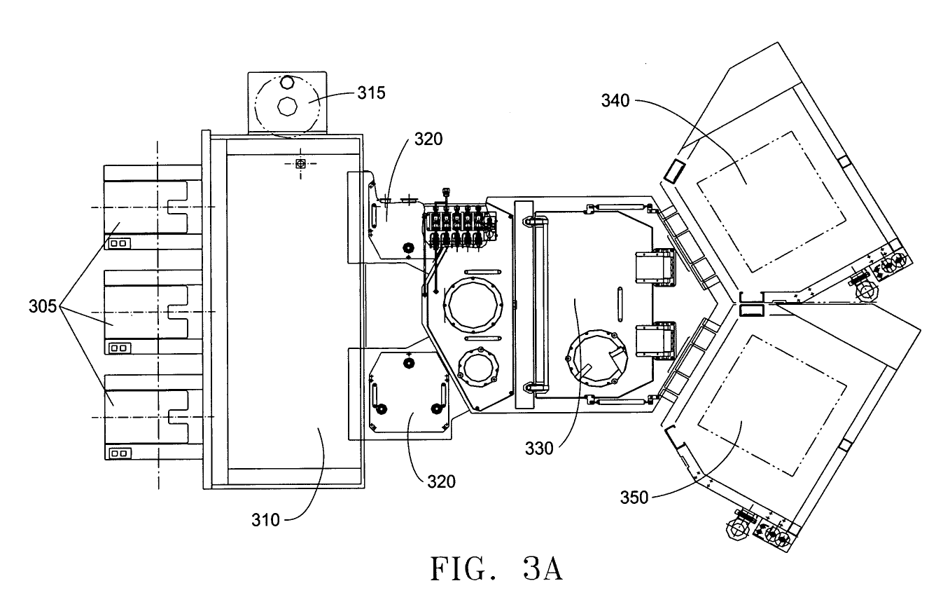

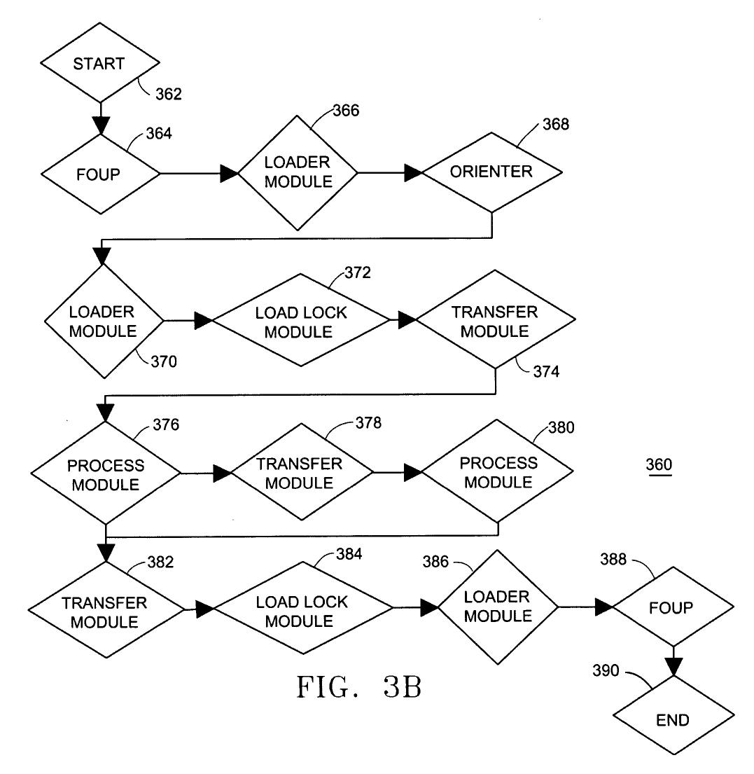

FIG. 3A illustrates a simplified block diagram for another semiconductor processing system in accordance with an embodiment of the invention. In the illustrated embodiment, a semiconductor processing system 300 for processing 300 mm or 200 mm wafers is shown. For example, the semiconductor processing system can be a Trias system from Tokyo Electron Limited (TEL).

As shown in the illustrated embodiment, a semiconductor processing system 300 can comprise a plurality of Front Opening Unified Pods (FOUPs) 305, a loader module 310, at least one orienting module 315, a plurality of load lock modules (LLM) 320, a transfer module 330, and a plurality of processing modules (340, 350).

In the illustrated embodiment, three FOUPs 305 are shown and one of the FOUPs 305 is used to store dummy wafers, one loader module 310 is shown, one orienting module (315) is shown, two load lock modules 320 are shown, one transfer module 330 is shown, and two processing modules (340, 350) are shown, but this is not required for the invention. In alternate embodiments, different configurations can be used, and the processing system can comprise additional components not shown in FIG. 3A.

In the illustrated embodiment, each FOUP 305 can comprise a plurality of wafers including dummy wafers. The FOUP 305 is a sealed environment to protect the wafers as they are transported among process tools around the fab. For example, the FOUPs can be SEMI compliant and contain up to twenty-five 300 mm wafers. Three FOUPs 305 can be coupled to the loader module 310 at one time. Two or more transfer mechanisms (not shown) can be used to transfer a wafer between the FOUP 305 and the loader module 310. For example, two transfer mechanisms can be used to increase throughput.

The wafer can be transferred to an orienting module 315 coupled to the loader module 310. The orienting module 315 can be used to center and align the position of the wafer relative to the notch in the wafer. The loader module can comprise one or more buffer stations (not shown). The loader module can comprise a HEPA filtered laminar flow environment to minimize particles during mechanical movements associated with wafer transfer.

As shown in FIG. 3A, two load lock modules 320 can be coupled to different transfer ports of the loader module. A transfer mechanism (not shown) can be used to transfer a wafer between a loader module 310 and a load lock module 320. In addition, the two load lock modules 320 can be coupled to different transfer ports of the transfer module 330. A transfer mechanism (not shown) can be used to transfer a wafer between a transfer module 330 and a load lock module 320.

In the illustrated embodiment, each of the processing modules (340, 350) can comprise at least one processing chamber (not shown) that can be used to process a wafer. For example, one or more of the processing modules (340, 350) can comprise a plasma enhanced deposition module as shown in FIG. 1. Alternately, one or more of the processing modules (340, 350) can comprise a chemical vapor deposition (CVD) module, a physical vapor deposition (PVD, iPVD) module, a atomic layer deposition (ALD) module, an etch module, a photoresist coating module, a patterning module, a development module, a thermal processing module, curing module, and/or combinations thereof.

As shown in FIG. 3A, the processing modules (340, 350) can be coupled to different transfer ports of the transfer module 330. A transfer mechanism (not shown) can be used to transfer a wafer between a processing module (340, 350) and the transfer module 330. For example, a wafer can be transferred to a first processing module where a first process is performed and then transferred to a second processing module where a second process is performed. In addition, a wafer can be processed using only one of the processing modules (340, 350).

FIG. 3B shows a simplified wafer flow diagram through the semiconductor processing system illustrated FIG. 3A. In the illustrated embodiment, an exemplary process flow 360 is shown. The process flow 360 can start in 362, and in 364, one or more FOUPs can be coupled to a processing system. In 366, a wafer can be moved from a FOUP into a loader module, and in 368, the wafer can be centered and/or aligned using an alignment assembly in an orienter module 315. In 370, the wafer can be moved into the loader module; in 372, the wafer can be moved into a load lock module; and in 374, the wafer can be moved into the transfer module. In 376, the wafer can be transferred into a processing module and processed. In 382, the processed wafer can be moved back into the transfer module; in 384, the processed wafer can be moved into the load lock module; in 386, the processed wafer can be moved into a loader module; and in 388, the processed wafer can be moved into the FOUP; and the process flow 360 can end in 390.

In another exemplary process flow, the processed wafer can be moved in 378 from a process module into the transfer module; and in 380, the processed wafer can be moved into another processing module where another process is performed. In 382, the processed wafer can be moved back into the transfer module and the process flow 360 can continue as shown in FIG. 3B. In alternate process flows, other process modules may be included, and different process flows can be used. For example, an integrated metrology module (IMM) may be coupled to the transfer module and/or a processing module, and measurements can be made using an IMM module before and/or after performing a process.

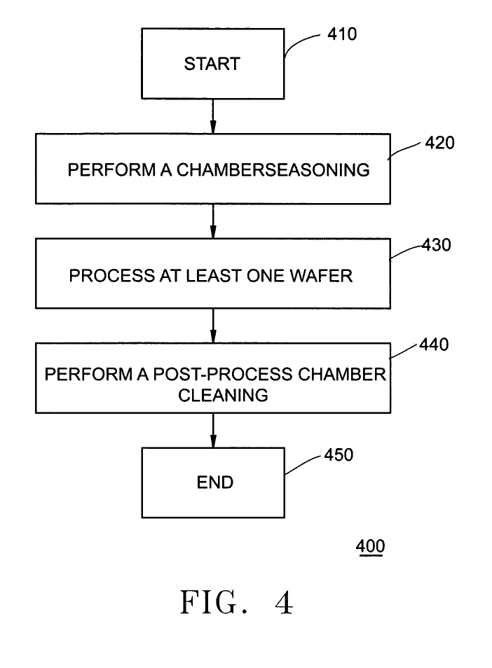

FIG. 4 shows a simplified flow diagram of a procedure for reducing the amount of particles deposited on a substrate in accordance with an embodiment of the invention. Procedure 400 starts in 410. For example, a dummy substrate can be inserted into the chamber and positioned on the substrate holder 130. Alternately a dummy substrate is not required. The substrate holder can be translatable and can be used to establish a gap between an upper electrode surface and a surface of the substrate holder.

In 420, a chamber seasoning process can be performed. A chamber seasoning process can comprise a chamber cleaning process and/or a chamber pre-coating process. In one embodiment, a cleaning process can be performed during a seasoning process. In an alternate embodiment, a cleaning process is not required during a seasoning process.

During a chamber cleaning process, a gap can be established between the upper electrode and a surface of the substrate holder, and the gap can range from approximately 1 mm to approximately 200 mm or alternatively, the gap can range from approximately 2 mm to approximately 150 mm. In addition, a first gap can be established during a first time, and a second gap can be established during a second time. In an alternate embodiment, the gap size can remain fixed. In other embodiments, the gap size can be changed more than once during the chamber cleaning process. Alternately at least one of pressure, RF power and gas flow can be varied through the cleaning process.

The first gap can vary from approximately 2 mm to approximately 200 mm, and the second gap can vary from approximately 2 mm to approximately 200 mm. Alternately, the first gap can vary from approximately 4 mm to approximately 80 mm, and the second gap can vary from approximately 10 mm to approximately 200 mm. In one example, the first gap can vary from approximately 6 mm to approximately 48 mm, and the second gap can vary from approximately 10 mm to approximately 125 mm.

The first time period can vary from approximately 0 seconds to approximately 3000 seconds, and the second time period can vary from approximately 0 seconds to approximately 3000 seconds. Alternately, the first time period can vary from approximately 0 seconds to approximately 2000 seconds, and the second time period can vary from approximately 0 seconds to approximately 2000 seconds. In one example, the first time period can vary from approximately 30 seconds to approximately 1200 seconds, and the second time period can vary from approximately 30 seconds to approximately 1200 seconds.

During the chamber cleaning process, a RF signal can be provided to the upper electrode using the first RF source to create and/or control a plasma. For example, the first RF source can operate in a frequency range from approximately 0.1 MHz. to approximately 200 MHz. Alternatively, the first RF source can operate in a frequency range from approximately 1 MHz. to approximately 100 MHz, or the first RF source can operate in a frequency range from approximately 2 MHz. to approximately 60 MHz. The first RF source can operate in a power range from approximately 0 watts to approximately 10000 watts, or alternatively, the first RF source can operate in a power range from approximately 10 watts to approximately 5000 watts. In another embodiment, the first RF source can operate in a power range from approximately 50 watts to approximately 2000 watts.

Alternately, during the chamber cleaning process, a RF signal can be provided to the lower electrode in the substrate holder using the second RF source to create and/or control a plasma. For example, the second RF source can operate in a frequency range from approximately 0.1 MHz. to approximately 200 MHz. Alternatively, the second RF source can operate in a frequency range from approximately 0.2 MHz. to approximately 30 MHz, or the second RF source can operate in a frequency range from approximately 0.3 MHz. to approximately 15 MHz. The second RF source can operate in a power range from approximately 0 watts to approximately 1000 watts, or alternatively, the second RF source can operate in a power range from approximately 0 watts to approximately 500 watts.

In various embodiments, a single RF source can be used and/or a combination of RF sources can be used during the chamber cleaning process.

Alternately remote plasma can be used with RF or instead of RF.

In one embodiment, a shower plate assembly can be provided in the processing chamber and can be coupled to the upper electrode. In alternate embodiments, different gas supply means can be provided. For example, a shower plate assembly can comprise a center region 122, an edge region 124, and a sub region 126, and the shower plate assembly can be coupled to a gas supply system. One or more process gases can be provided to the center region, one or more process gases can be provided to the edge region and one or more process gases can be provided to the sub region during the chamber cleaning process. The process gases provided to the different regions can be the same or different.

Alternately, the center region and the edge region can be coupled together as a single primary region, and gas supply system can provide the first process gas and/or the second process gas to the primary region. In alternate embodiments, any of the regions can be coupled together and the gas supply system can provide one or more process gasses.

During a chamber cleaning process, a fluorine-containing gas, an oxygen-containing gas, or an inert gas, or a combination of two or more thereof can be used. The fluorine-containing gas can comprise NF₃, CF₄, C₂F₆, C₃F₈, C₄F₈, SF₆, CHF₃, F₂, or COF₂, or a combination of two or more thereof. The oxygen-containing gas can comprise O₂, O₃, CO, NO, N₂O, or CO₂, or a combination of two or more thereof. The inert gas can comprise argon, helium, or nitrogen, or a combination of two or more thereof.

In addition, a fluorine-containing gas can have a flow rate that varies from approximately 0 sccm to approximately 10000 sccm, an oxygen containing gas can have a flow rate that varies from approximately 0 scorn to approximately 10000 sccm, and an inert gas can have a flow rate that varies from approximately 0 sccm to approximately 10000 sccm. Alternatively, a fluorine-containing gas can have a flow rate that varies from approximately 10 sccm to approximately 5000 sccm, an oxygen containing gas can have a flow rate that varies from approximately 10 sccm to approximately 5000 sccm, and an inert gas can have a flow rate that varies from approximately 10 sccm to approximately 5000 sccm.

Also, a temperature control system can be coupled to the substrate holder, and the substrate holder temperature can be controlled using the temperature control system during a chamber cleaning process. The substrate holder temperature can range from approximately 0° C. to approximately 500° C., or alternately, the substrate holder temperature can range from approximately 200° C. to approximately 500° C. For example, the substrate holder temperature can range from approximately 250° C. to approximately 400° C. The temperature control system can also be coupled to a chamber wall, and the temperature of the chamber wall can be controlled using the temperature control system. For example, the temperature of the chamber wall can range from approximately 0° C. to approximately 500° C. In addition, the temperature control system can be coupled to the shower plate assembly; and the temperature of the shower plate assembly can be controlled using the temperature control system. For example, the temperature of the shower plate assembly can range from approximately 0° C. to approximately 500° C.

Furthermore, a pressure control system can be coupled to the chamber, and the chamber pressure can be controlled using the pressure control system during a chamber cleaning process. The chamber pressure can range from approximately 0.1 mTorr to approximately 100 Torr.

During the chamber cleaning process, an ESC voltage is not required. Alternately, the ESC voltage can be used during the chamber cleaning process.

In one embodiment, a chamber pre-coating process can be performed during a seasoning process. In an alternate embodiment, a chamber pre-coating process is not required during a seasoning process.

During a chamber pre-coating process, a gap can be established, and the gap can range from approximately 1 mm to approximately 200 mm or alternatively, the gap can range from approximately 2 mm to approximately 150 mm. In one embodiment, the gap size can remain fixed. In alternate embodiments, a first gap can be established during a first time, and a second gap can be established during a second time. In other embodiments, the gap size can be changed more than once during the chamber pre-coating process. In one example, the gap can vary from approximately 10.0 mm to approximately 30.0 mm. Alternately at least one of pressure, RF power and precursor flow can be varied through the pre-coating process.

The pre-coating time period can vary from approximately 0 seconds to approximately 3000 seconds, or alternately, the pre-coating time period can vary from approximately 0 seconds to approximately 600 seconds. In one example, the pre-coating time period can vary from approximately 20 seconds to approximately 300 seconds.

During the chamber pre-coating process, a RF signal can be provided to the upper electrode using the first RF source to create and/or control a plasma. For example, the first RF source can operate in a frequency range from approximately 0.1 MHz. to approximately 200 MHz. Alternatively, the first RF source can operate in a frequency range from approximately 1 MHz. to approximately 100 MHz, or the first RF source can operate in a frequency range from approximately 2 MHz. to approximately 60 MHz. The first RF source can operate in a power range from approximately 10 watts to approximately 10000 watts, or alternatively, the first RF source can operate in a power range from approximately 10 watts to approximately 5000 watts. In another embodiment, the first RF source can operate in a power range from approximately 100 watts to approximately 2000 watts.

Alternately, during the chamber pre-coating process, a RF signal can be provided to the lower electrode in the substrate holder using the second RF source to create and/or control a plasma. For example, the second RF source can operate in a frequency range from approximately 0.1 MHz. to approximately 200 MHz. Alternatively, the second RF source can operate in a frequency range from approximately 0.2 MHz. to approximately 30 MHz, or the second RF source can operate in a frequency range from approximately 0.3 MHz. to approximately 15 MHz. The second RF source can operate in a power range from approximately 0 watts to approximately 1000 watts, or alternatively, the second RF source can operate in a power range from approximately 0 watts to approximately 500 watts.

In various embodiments, a single RF source can be used and/or a combination of RF sources can be used during the chamber pre-coating process.

In one embodiment, a shower plate assembly can be provided in the processing chamber and can be coupled to the upper electrode. In alternate embodiments, different gas supply means can be provided. For example, a shower plate assembly can comprise a center region 122, an edge region 124, and a sub region 126, and the shower plate assembly can be coupled to a gas supply system. During the chamber pre-coating process, one or more process gases can be provided to the center region, one or more process gases can be provided to the edge region and one or more process gases can be provided to the sub region during the chamber pre-coating process. The process gases provided to the different regions can be the same or different.

Alternately, the center region and the edge region can be coupled together as a single primary region, and gas supply system can provide the first process gas and/or the second process gas to the primary region. In alternate embodiments, any of the regions can be coupled together and the gas supply system can provide one or more process gasses.

During a chamber pre-coating process, a silicon-containing precursor, a carbon containing precursor, or an inert gas can be used, or a combination of two or more thereof. The silicon-containing precursor can comprise monosilane (SiH₄), tetraethylorthosilicate (TEOS), monomethylsilane (1MS), dimethylsilane (2MS), trimethylsilane (3MS), tetramethylsilane (4MS), octamethylcyclotetrasiloxane (OMCTS), or tetramethylcyclotetrasilane (TMCTS), or a combination of two or more thereof. The carbon-containing gas can comprise CH₄, C₂H₆, C₂H₄, C₂H₂, C₆H₆, or C₆H₅OH, or a combination of two or more thereof. The inert gas can comprise at least one of argon, helium, or nitrogen, or a combination of two or more thereof.

In addition, a silicon-containing precursor and a carbon-containing precursor can have a flow rate that varies from approximately 0 sccm to approximately 2000 sccm, and an inert gas can have a flow rate that varies from approximately 0 sccm to approximately 5000 sccm. Alternatively, a silicon-containing precursor and carbon-containing precursor can have a flow rate that varies from approximately 10 sccm to approximately 1000 sccm, and an inert gas can have a flow rate that varies from approximately 10 sccm to approximately 2000 sccm.

Also, a temperature control system can be coupled to the substrate holder, and the substrate holder temperature can be controlled during the chamber pre-coating process using the temperature control system. The substrate holder temperature can range from approximately 0° C. to approximately 500° C., or alternately, the substrate holder temperature can range from approximately 200° C. to approximately 500° C. For example, the substrate holder temperature can range from approximately 250° C. to approximately 400° C. The temperature control system can also be coupled to a chamber wall, and the temperature of the chamber wall can be controlled using the temperature control system. For example, the temperature of the chamber wall can range from approximately 0° C. to approximately 500° C. In addition, the temperature control system can be coupled to the shower plate assembly; and the temperature of the shower plate assembly can be controlled using the temperature control system. For example, the temperature of the shower plate assembly can range from approximately 0° C. to approximately 500° C.

Furthermore, a pressure control system can be coupled to the chamber, and the chamber pressure can be controlled during the chamber pre-coating process using the pressure control system. The chamber pressure can range from approximately 0.1 mTorr to approximately 100 Torr. For example, the chamber pressure can range from approximately 0.1 Torr to approximately 10 Torr.

During the chamber pre-coating process, an ESC voltage is not required. Alternately, the ESC voltage can be used during the chamber pre-coating process.

In 430, a deposition process can be performed. Alternately, a deposition process can be performed at a different time. During a deposition process at least one substrate can be processed, and at least one layer can be deposited. In one embodiment, during a deposition process a TERA layer can be deposited. Alternately, a different type of film can be deposited.

During a deposition process, a RF signal can be provided to the upper electrode using the first RF source. For example, the first RF source can operate in a frequency range from approximately 0.1 MHz. to approximately 200 MHz. Alternatively, the first RF source can operate in a frequency range from approximately 1 MHz. to approximately 100 MHz, or the first RF source can operate in a frequency range from approximately 2 MHz. to approximately 60 MHz. The first RF source can operate in a power range from approximately 10 watts to approximately 10000 watts, or alternatively, the first RF source can operate in a power range from approximately 10 watts to approximately 5000 watts.

Alternately, during a deposition process, a RF signal can be provided to the lower electrode in the substrate holder using the second RF source. For example, the second RF source can operate in a frequency range from approximately 0.1 MHz. to approximately 200 MHz. Alternatively, the second RF source can operate in a frequency range from approximately 0.2 MHz. to approximately 30 MHz, or the second RF source can operate in a frequency range from approximately 0.3 MHz. to approximately 15 MHz. The second RF source can operate in a power range from approximately 0 watts to approximately 1000 watts, or alternatively, the second RF source can operate in a power range from approximately 0 watts to approximately 500 watts.

In various embodiments, a single RF source can be used and/or a combination of RF sources can be used during a deposition process.

In one embodiment, a shower plate assembly can be provided in the processing chamber and can be coupled to the upper electrode. In alternate embodiments, different gas supply means can be provided. For example, a shower plate assembly can comprise a center region 122, an edge region 124, and a sub region 126, and the shower plate assembly can be coupled to a gas supply system. During the deposition process, one or more process gases can be provided to the center region, one or more process gases can be provided to the edge region and one or more process gases can be provided to the sub region during the deposition process. The process gases provided to the different regions can be the same or different.

Alternately, the center region and the edge region can be coupled together as a single primary region, and gas supply system can provide the first process gas and/or the second process gas to the primary region. In alternate embodiments, any of the regions can be coupled together and the gas supply system can provide one or more process gasses.

During a deposition process, the process gas can comprise a silicon-containing precursor, a carbon-containing precursor, an oxygen-containing gas, a nitrogen-containing gas, or an inert gas, or a combination of two or more thereof. The flow rate for the silicon-containing precursor and the carbon containing gas can range from approximately 0 sccm to approximately 5000 sccm. The silicon-containing precursor can comprise monosilane (SiH₄), tetraethylorthosilicate (TEOS), monomethylsilane (1MS), dimethylsilane (2MS), trimethylsilane (3MS), tetramethylsilane (4MS), octamethylcyclotetrasiloxane (OMCTS), tetramethylcyclotetrasilane (TMCTS), or dimethyldimethoxysilane (DMDMOS), or a combination of two or more thereof. The carbon-containing gas can comprise CH₄, C₂H₆, C₂H₄, C₂H₂, C₆H₆, or C₆H₅OH, or a combination of two or more thereof. The oxygen-containing gas can comprise O₂, CO, NO, N₂O, or CO₂, or a combination of two or more thereof; the nitrogen-containing gas can comprise N₂, or NH₃, or a combination thereof; and the inert gas can comprise at least one of Ar, or He, or a combination thereof. The inert gas can have a flow rate that varies from approximately 0 sccm to approximately 10000 sccm. Alternatively, an inert gas can have a flow rate that varies from approximately 10 sccm to approximately 5000 sccm.

Also, a temperature control system can be coupled to the substrate holder, and the substrate holder temperature can be controlled during a deposition process using the temperature control system. The substrate holder temperature can range from approximately 0° C. to approximately 500° C., or alternately, the substrate holder temperature can range from approximately 200° C. to approximately 500° C. For example, the substrate holder temperature can range from approximately 250° C. to approximately 400° C. The temperature control system can also be coupled to a chamber wall, and the temperature of the chamber wall can be controlled using the temperature control system. For example, the temperature of the chamber wall can range from approximately 0° C. to approximately 500° C. In addition, the temperature control system can be coupled to the shower plate assembly; and the temperature of the shower plate assembly can be controlled using the temperature control system. For example, the temperature of the shower plate assembly can range from approximately 0° C. to approximately 500° C.

Furthermore, a pressure control system can be coupled to the chamber, and the chamber pressure can be controlled during the deposition process using the pressure control system. The chamber pressure can range from approximately 0.1 mTorr to approximately 100 Torr. For example, the chamber pressure can range from approximately 0.1 Torr to approximately 20 Torr.

During the deposition process, an ESC voltage is not required. Alternately, the ESC voltage can be used during the deposition process.

For example, a TERA layer can have a thickness of approximately 150 A to approximately 10000 A. A TERA layer can be deposited on an oxide layer or other type of layer. A TERA layer can comprise a material having a refractive index (n) ranging from approximately 1.5 to approximately 2.5 when measured at a wavelength of at least one of: 248 nm, 193 nm, and 157 nm, and an extinction coefficient (k) ranging from approximately 0.1 to approximately 0.9 when measured at a wavelength of at least one of: 248 nm, 193 nm, and 157 nm. The deposition rate can range from approximately 100 A/min to approximately 10000 A/min. The deposition time can vary from approximately 5 seconds to approximately 180 seconds. The substrate to substrate thickness uniformity can be less than one percent as one sigma with this invention.

In 440, a post-process chamber cleaning process can be performed. In an alternate embodiment, a post-process chamber cleaning process is not required.

During a post-process chamber cleaning process, a gap can be established, and the gap can range from approximately 1 mm to approximately 200 mm or alternatively, the gap can range from approximately 2 mm to approximately 150 mm. In addition, a first gap can be established during a first time, and a second gap can be established during a second time. In an alternate embodiment, the gap size can remain fixed. In other embodiments, the gap size can be changed more than once during the post-process chamber cleaning process.

The first gap can vary from approximately 2 mm to approximately 200 mm, and the second gap can vary from approximately 2 mm to approximately 200 mm. Alternately, the first gap can vary from approximately 4 mm to approximately 120 mm, and the second gap can vary from approximately 10 mm to approximately 200 mm. In one example, the first gap can vary from approximately 10 mm to approximately 50 mm, and the second gap can vary from approximately 10 mm to approximately 125 mm. Alternately pressure, RF power and gas flow can be varied through the post cleaning process. Alternately remote plasma can be used with RF or instead of RF.

The first time period can vary from approximately 0 seconds to approximately 3000 seconds, and the second time period can vary from approximately 0 seconds to approximately 3000 seconds. Alternately, the first time period can vary from approximately 0 seconds to approximately 2000 seconds, and the second time period can vary from approximately 0 seconds to approximately 2000 seconds. In one example, the first time period can vary from approximately 20 seconds to approximately 1200 seconds, and the second time period can vary from approximately 20 seconds to approximately 1200 seconds.

During the post-process chamber cleaning process, a RF signal can be provided to the upper electrode using the first RF source. For example, the first RF source can operate in a frequency range from approximately 0.1 MHz. to approximately 200 MHz. Alternatively, the first RF source can operate in a frequency range from approximately 1 MHz. to approximately 100 MHz, or the first RF source can operate in a frequency range from approximately 2 MHz. to approximately 60 MHz. The first RF source can operate in a power range from approximately 0 watts to approximately 10000 watts, or alternatively, the first RF source can operate in a power range from approximately 10 watts to approximately 5000 watts. In another embodiment, the first RF source can operate in a power range from approximately 100 watts to approximately 2000 watts.

Alternately, during the post-process chamber cleaning process, a RF signal can be provided to the lower electrode in the substrate holder using the second RF source. For example, the second RF source can operate in a frequency range from approximately 0.1 MHz. to approximately 200 MHz. Alternatively, the second RF source can operate in a frequency range from approximately 0.2 MHz. to approximately 30 MHz, or the second RF source can operate in a frequency range from approximately 0.3 MHz. to approximately 15 MHz. The second RF source can operate in a power range from approximately 0 watts to approximately 1000 watts, or alternatively, the second RF source can operate in a power range from approximately 0 watts to approximately 500 watts.

In various embodiments, a single RF source can be used and/or a combination of RF sources can be used during the post-process chamber cleaning process.

In one embodiment, a shower plate assembly can be provided in the processing chamber and can be coupled to the upper electrode. In alternate embodiments, different gas supply means can be provided. For example, a shower plate assembly can comprise a center region 122, an edge region 124, and a sub region 126, and the shower plate assembly can be coupled to a gas supply system. One or more process gases can be provided to the center region, one or more process gases can be provided to the edge region and one or more process gases can be provided to the sub region during the post-process chamber cleaning process. The process gases provided to the different regions can be the same or different.

Alternately, the center region and the edge region can be coupled together as a single primary region, and gas supply system can provide the first process gas and/or the second process gas to the primary region. In alternate embodiments, any of the regions can be coupled together and the gas supply system can provide one or more process gasses.

During a post-process chamber cleaning process, a fluorine-containing gas, an oxygen-containing gas, or an inert gas can be used, or a combination of two or more thereof. The fluorine-containing gas can comprise NF₃, CF₄, C₂F₆, C₃F₈, C₄F₈, SF₆, CHF₃, F₂, or COF₂, or a combination of two or more thereof. The oxygen-containing gas can comprise O₂, O3, CO, NO, N₂O, or CO₂, or a combination of two or more thereof. The inert gas can comprise argon, helium, or nitrogen, or a combination of two or more thereof.

In addition, a fluorine-containing gas can have a flow rate that varies from approximately 0 sccm to approximately 10000 sccm, an oxygen containing gas can have a flow rate that varies from approximately 0 sccm to approximately 10000 sccm, and an inert gas can have a flow rate that varies from approximately 0 sccm to approximately 10000 sccm. Alternatively, a fluorine-containing gas can have a flow rate that varies from approximately 10 sccm to approximately 5000 sccm, an oxygen containing gas can have a flow rate that varies from approximately 10 sccm to approximately 5000 sccm, and an inert gas can have a flow rate that varies from approximately 10 sccm to approximately 5000 sccm.

Also, a temperature control system can be coupled to the substrate holder, and the substrate holder temperature can be controlled using the temperature control system during the post-process chamber cleaning process. The substrate holder temperature can range from approximately 0° C. to approximately 500° C., or alternately, the substrate holder temperature can range from approximately 200° C. to approximately 500° C. For example, the substrate holder temperature can range from approximately 250° C. to approximately 400° C. The temperature control system can also be coupled to a chamber wall, and the temperature of the chamber wall can be controlled using the temperature control system. For example, the temperature of the chamber wall can range from approximately 0° C. to approximately 500° C. In addition, the temperature control system can be coupled to the shower plate assembly; and the temperature of the shower plate assembly can be controlled using the temperature control system. For example, the temperature of the shower plate assembly can range from approximately 0° C. to approximately 500° C.

Furthermore, a pressure control system can be coupled to the chamber, and the chamber pressure can be controlled using the pressure control system during the post-process chamber cleaning process. The chamber pressure can range from approximately 0.1 mTorr to approximately 100 Torr.

During the post-process chamber cleaning process, an ESC voltage is not required. Alternately, the ESC voltage can be used during the post-process chamber cleaning process.

Procedure 400 ends in 450.

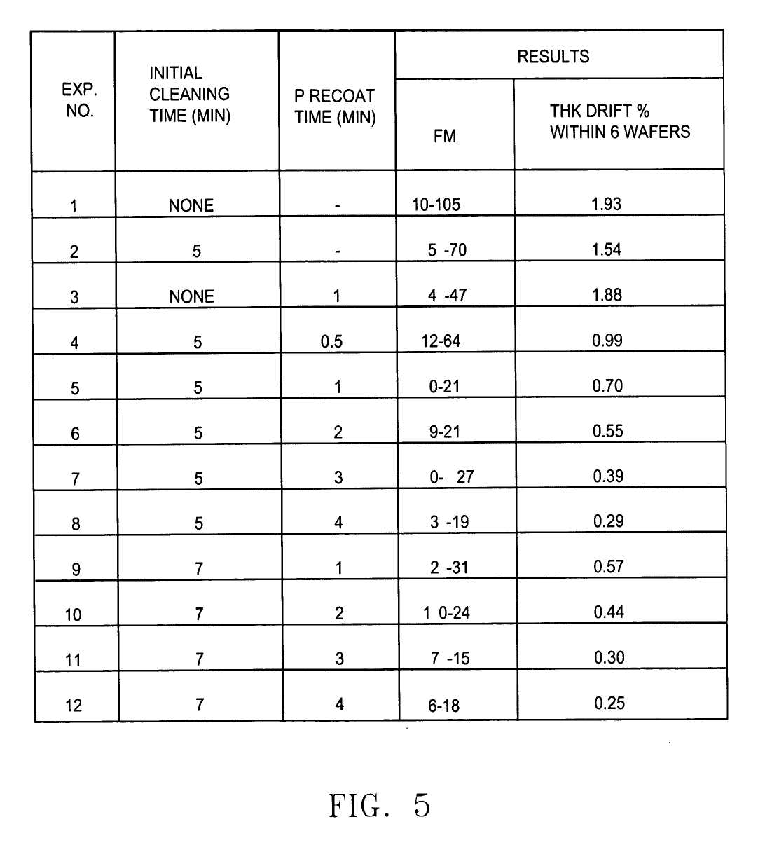

FIG. 5 illustrates a table of summary results for processes that were performed to verify the methods of the invention. A number of exemplary processes were performed and the results were examined with respect to wafer-to-wafer foreign material (FM) data, thickness drift data. The results are shown for twelve different experiments that were performed using different initial cleaning recipes and different precoat recipes. Six wafers were used in each experiment.

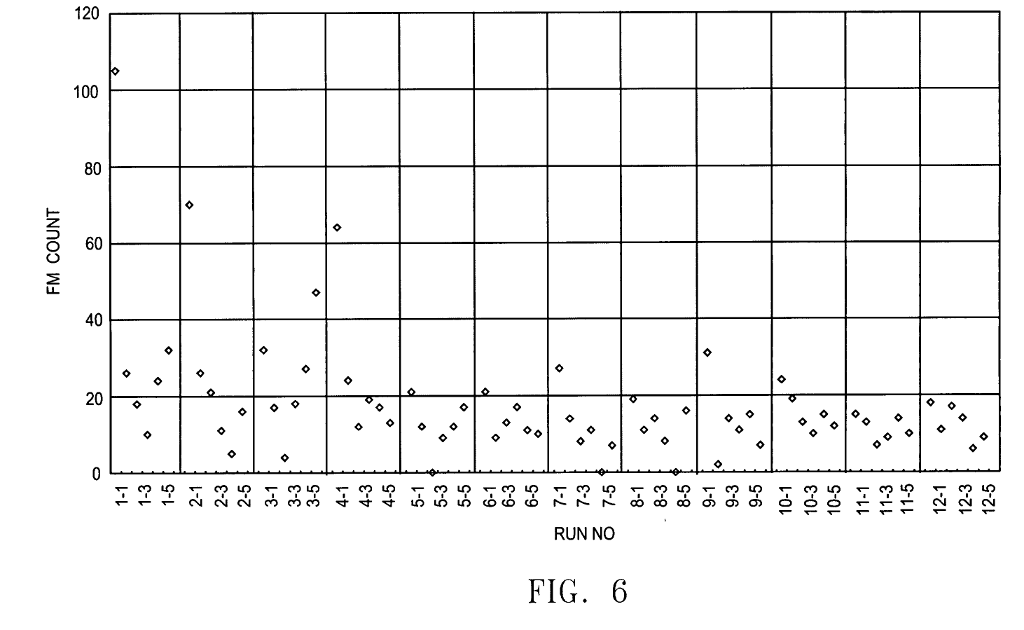

FIG. 6 illustrates a graph of the foreign material (FM) data for processes that were performed to verify the methods of the invention. The results show a wide range of results for the twelve experiments that were performed. During each experiment, six wafers were used, and the data points are identified using and experiment number and a wafer number (i.e., 1-1) In several experiments (5-12), some or all of the wafers had foreign material counts that were less than thirty. In all of the experiments, one or more of the wafers had a foreign material count that was less than fifteen. In one experiment, (1), one or more of the wafers had a foreign material count that was more than one hundred. In one embodiment, a high FM delta value can be less than approximately 80, and a median delta value can be less than approximately 20.

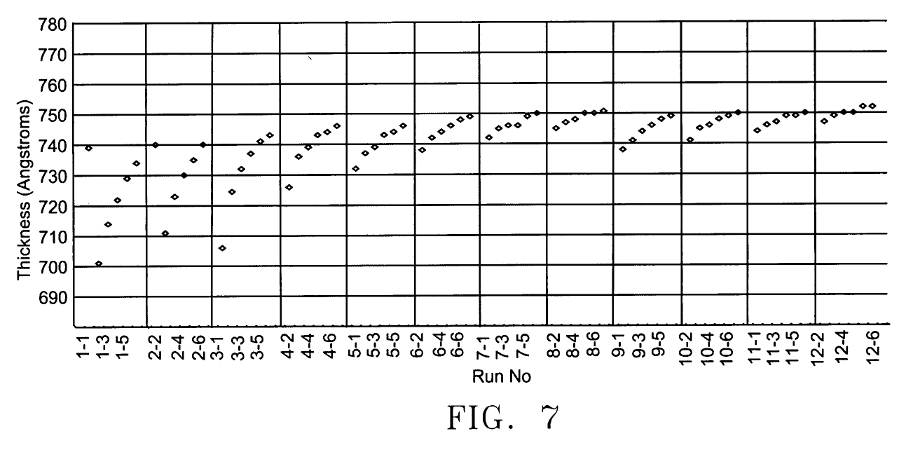

FIG. 7 illustrates a graph of the average thickness for processes that were performed to verify the methods of the invention. The results show a wide range of results for the twelve experiments that were performed. In several experiments, (9-12), the thickness range was less than 2 nm. In one embodiment, a target value of thickness variation can be less than approximately 1.0% as a 1-sigma value. The invention minimizes the thickness drift within a lot by performing a seasoning process before the actual deposition process.

The FM data was taken using a KLA-Tencor Surfscan SP1, and the FM data showed that a satisfactory particle count can be achieved. The measured data also showed that the one-sigma variation for the thickness drift was less than one percent.

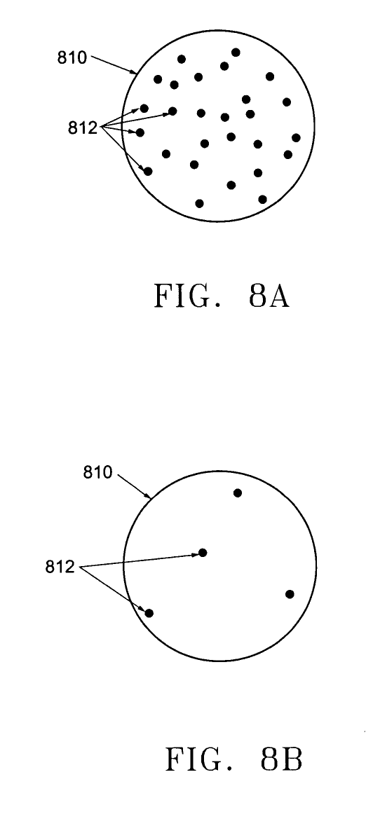

FIG. 8A shows an exemplary view of particle contamination on a substrate using a chamber that is left without post cleaning and residual deposition on chamber wall and showerhead, which comes from deposition prior to the monitor wafer. To determine the amount of particles (>0.16 um in size) being generated in the chamber, a test substrate was inserted into the un-cleaned chamber for a measured length of time. A high particle count (as shown FIG. 8A) resulted when an un-cleaned chamber was used. For example, after a 13.4 hour time period, a particle count of approximately 286 particles per substrate was measured. This result showed that approximately 21.3 particles per hour were being generated within the un-cleaned chamber.

FIG. 8B shows an exemplary view of particle contamination on a substrate in accordance with an embodiment of the invention. In one embodiment, post cleaning can be performed in the chamber after the normal deposition. For example, post plasma cleaning and/or a remote plasma cleaning and combination of thereof can be performed. To determine the amount of particles (>0.16 um in size) being generated in the cleaned chamber, a test substrate was inserted into the cleaned chamber for a measured length of time. A low particle count (as shown FIG. 8B) resulted when a seasoned chamber was used. For example, after a 13.4 hour time period, a particle count of approximately 44 particles per substrate was measured. This result showed that approximately 3.3 particles per hour were being generated within the cleaned chamber.

The invention provides a method and apparatus for depositing layers, such as TERA layers, that are uniform and substantially free of foreign material (contaminants).

In one embodiment, the initial and post cleaning process can comprise a main etch step and an over etch step. Alternately, a cleaning process may include a different number of steps, and other processes. In one exemplary cleaning process the 1st step (main etch) can include the following process conditions: NF₃ flow rate can vary from approximately 100 sccm to approximately 1000 sccm, or alternately from approximately 200 sccm to approximately 600 sccm; O₂ flow rate can vary from approximately 50 sccm to approximately 500 sccm, or alternately from approximately 225 sccm to approximately 275 sccm; He flow rate can vary from approximately 600 sccm to approximately 1000 sccm, or alternately from approximately 720 sccm to approximately 880 sccm; the top RF (TRF) power can vary from approximately 800 W to approximately 1200 W, or alternately from approximately 900 W to approximately 1100 W; the chamber pressure can vary from approximately 0.4 Torr to approximately 0.6 Torr, or alternately from approximately 0.45 Torr to approximately 0.55 Torr; and the gap can vary from approximately 10 mm to approximately 30 mm, or alternately from approximately 15 mm to approximately 21 mm. Furthermore, the 2nd step (over etch) can include the following process conditions: NF₃ flow rate can vary from approximately 450 sccm to approximately 550 sccm, or alternately from approximately 475 sccm to approximately 525 sccm; O₂ flow rate can vary from approximately 200 sccm to approximately 300 sccm, or alternately from approximately 225 sccm to approximately 275 sccm; He flow rate can vary from approximately 600 sccm to approximately 1000 sccm, or alternately from approximately 720 sccm to approximately 880 sccm; the top RF (TRF) power can vary from approximately 100 W to approximately 300 W, or alternately from approximately 150 W to approximately 250 W; the chamber pressure can vary from approximately 0.4 Torr to approximately 0.6 Torr, or alternately from approximately 0.45 Torr to approximately 0.55 Torr; and the gap can vary from approximately 80 mm to approximately 160 mm, or alternately from approximately 100 mm to approximately 130 mm.

In another exemplary cleaning process the 1st step (main etch) can include the following process conditions: NF₃ flow rate can vary from approximately 450 sccm to approximately 675 sccm, or alternately from approximately 560 sccm to approximately 620 sccm; O₂ flow rate can vary from approximately 140 sccm to approximately 300 sccm, or alternately from approximately 160 sccm to approximately 210 sccm; He flow rate can vary from approximately 800 sccm to approximately 1200 sccm, or alternately from approximately 900 sccm to approximately 1100 sccm; the top RF (TRF) power can vary from approximately 200 W to approximately 600 W, or alternately from approximately 300 W to approximately 500 W; the bottom RF (BRF) power can vary from approximately 0 W to approximately 200 W, or alternately from approximately 20 W to approximately 120 W; the chamber pressure can vary from approximately 0.4 Torr to approximately 0.6 Torr, or alternately from approximately 0.45 Torr to approximately 0.55 Torr; and the gap can vary from approximately 5 mm to approximately 60 mm, or alternately from approximately 15 mm to approximately 30 mm. Additionally, the 2nd step (over etch) can include the following process conditions: NF₃ flow rate varies from approximately 100 sccm to approximately 500 sccm, or alternately from approximately 200 sccm to approximately 400 sccm; O₂ flow rate can vary from approximately 10 sccm to approximately 300 sccm, or alternately from approximately 60 sccm to approximately 140 sccm; Ar flow rate can vary from approximately 1000 sccm to approximately 2000 sccm, or alternately from approximately 1300 sccm to approximately 1700 sccm; the top RF (TRF) power can vary from approximately 0.0 W to approximately 300 W, or alternately from approximately 0.0 W to approximately 250 W; the chamber pressure can vary from approximately 3 Torr to approximately 5 Torr, or alternately from approximately 3.5 Torr to approximately 4.5 Torr; and the gap can vary from approximately 80 mm to approximately 160 mm, or alternately from approximately 100 mm to approximately 130 mm. In alternate embodiments, remote plasma may be used during the cleaning process, and the power provided to the remote plasma generator can vary from approximately 0 W to approximately 3000 W, or alternately from approximately 1000 W to approximately 2700 W.

In one embodiment, the pre-coating process can include a deposition process that includes a single coating material, such as a SiC material or a SiO₂ material. Alternately, the pre-coating process may include a deposition process that can include different coating materials, a different number of layers, and other processes.

In one exemplary pre-coating process, a first material (i.e. SiC material) can be used, and the pre-coating process can include the following process conditions: 3MS flow rate can vary from approximately 50 sccm to approximately 300 sccm, or alternately from approximately 100 sccm to approximately 200 sccm; He flow rate can vary from approximately 1000 sccm to approximately 2000 sccm, or alternately from approximately 1100 sccm to approximately 1300 sccm; the top RF (TRF) power can vary from approximately 600 W to approximately 1000 W, or alternately from approximately 700 W to approximately 900 W; the chamber pressure can vary from approximately 4 Torr to approximately 10 Torr, or alternately from approximately 6 Torr to approximately 8 Torr; and the gap can vary from approximately 5 mm to approximately 50 mm, or alternately from approximately 10 mm to approximately 30 mm.

In another exemplary pre-coating process, a second material (i.e. SiO₂ material) can be used, and the pre-coating process can include the following process conditions: SiH₄ flow rate can vary from approximately 20 sccm to approximately 300 sccm, or alternately from approximately 50 sccm to approximately 150 sccm; N₂O flow rate can vary from approximately 300 sccm to approximately 1000 sccm, or alternately from approximately 400 sccm to approximately 600 sccm; the top RF (TRF) power can vary from approximately 200 W to approximately 1000 W, or alternately from approximately 300 W to approximately 500 W; the chamber pressure can vary from approximately 1 Torr to approximately 5 Torr, or alternately from approximately 2 Torr to approximately 4 Torr; and the gap can vary from approximately 5 mm to approximately 50 mm, or alternately from approximately 10 mm to approximately 30 mm.

During cleaning and pre-coating processes the substrate holder temperature can vary from approximately 250° C. to approximately 350° C. or alternately from approximately 290° C. to approximately 330° C.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

1. A method for operating a plasma enhanced chemical vapor deposition (PECVD) system, the method comprising:
performing a chamber seasoning process, wherein the chamber seasoning process comprises a chamber cleaning process, or a chamber pre-coating process, or a combination thereof, wherein the chamber cleaning process, when employed, uses a fluorine-containing gas, an oxygen-containing gas, or an inert gas, or a combination of two or more thereof, and wherein the chamber pre-coating process, when employed, uses a silicon-containing precursor, a carbon containing precursor, or an inert gas, or a combination of two or more thereof;
positioning a substrate on a substrate holder in the processing chamber;
depositing a film on the substrate, wherein a processing gas comprising a precursor is provided to the processing chamber during the deposition process; and
removing the substrate from the processing chamber.

2. The method as claimed in claim 1, further comprising:
positioning a new substrate on the substrate holder in the processing chamber;
depositing a film on the new substrate, wherein a processing gas comprising a precursor is provided to the processing chamber during the deposition process; and
removing the new substrate from the processing chamber.

3. The method as claimed in claim 2, further comprising:
performing a post-process chamber cleaning process, wherein the post-process chamber cleaning process uses a fluorine-containing gas, an oxygen-containing gas, or an inert gas, or a combination of two or more thereof.

4. The method as claimed in claim 3, wherein the post-process chamber cleaning process uses the fluorine-containing gas which comprises NF₃, CF₄, C₂F₆, C₃F₈, C₄F₈, SF₆, CHF₃, F₂, or COF₂, or a combination of two or more thereof.

5. The method as claimed in claim 3, wherein the post-process chamber cleaning process uses the oxygen-containing gas which comprises H₂O, NO, N₂O, O₂, O₃, CO, or CO₂, or a combination of two or more thereof.

6. The method as claimed in claim 3, wherein the post-process chamber cleaning process uses the inert gas which comprises Ar, He, or N₂, or a combination of two or more thereof.

7. The method as claimed in claim 3, further comprising:
positioning a dummy substrate on the substrate holder before performing the post-process chamber cleaning process; and
removing the dummy substrate after performing the post-process chamber cleaning process.

8. The method as claimed in claim 2, wherein the film on the substrate comprises a Tunable Etch Resistant ARC (TERA) material, and the film on the new substrate comprises substantially the same TERA material.

9. The method as claimed in claim 1, wherein the film on the substrate comprises a Tunable Etch Resistant ARC (TERA) material.

10. The method as claimed in claim 1, further comprising:
positioning a dummy substrate on the substrate holder before performing the chamber seasoning process; and
removing the dummy substrate after performing the chamber seasoning process.

11. The method as claimed in claim 1, wherein the chamber seasoning process includes the chamber cleaning process and the chamber cleaning process employs the fluorine-containing gas comprising NF₃, CF₄, C₂F₆, C₃F₈, C₄F₈, SF₆, CHF₃, F₂, or COF₂, or a combination of two or more thereof.

12. The method as claimed in claim 1, wherein the chamber seasoning process includes the chamber cleaning process and the chamber cleaning process employs the oxygen-containing gas comprising H₂O, NO, N₂O, O₂, O₃, CO, or CO₂, or a combination of two or more thereof.

13. The method as claimed in claim 1, wherein the chamber seasoning process includes the chamber pre-coating process and the chamber pre-coating process employs the silicon-containing precursor comprising monosilane (SiH₄), tetraethylorthosilicate (TEOS), monomethylsilane (1MS), dimethylsilane (2MS), trimethylsilane (3MS), tetramethylsilane (4MS), octamethylcyclotetrasiloxane (OMCTS), tetramethylcyclotetrasilane (TMCTS), or dimethyldimethoxysilane (DMDMOS), or a combination of two or more thereof.

14. The method as claimed in claim 1, wherein the chamber seasoning process includes the chamber pre-coating process and the chamber pre-coating process employs the carbon-containing gas comprising CH₄, C₂H₆, C₂H₄, C₂H₂, C₆H₆, or C₆H₅OH, or a combination of two or more thereof.

15. The method as claimed in claim 1, wherein the chamber seasoning process includes the chamber cleaning process and the chamber cleaning process employs the inert gas comprising Ar, He, or N₂, or a combination of two or more thereof.

16. The method as claimed in claim 1, wherein the chamber seasoning process includes the chamber pre-coating process and the chamber pre-coating process employs the inert gas comprising Ar, He, or N₂, or a combination of two or more thereof.

17. The method as claimed in claim 1, wherein the PECVD system comprises an RF source and the chamber seasoning process includes the chamber cleaning process which further comprises:
operating the RF source in a frequency range from approximately 0.1 MHz. to approximately 200 MHz; and
operating the RF source in a power range from approximately 0 watts to approximately 10000 watts.

18. The method as claimed in claim 1, wherein the PECVD system comprises an RF source and the chamber seasoning process includes the chamber pre-coating process which further comprises:
operating the RF source in a frequency range from approximately 0.1 MHz. to approximately 200 MHz; and
operating the RF source in a power range from approximately 0.1 watts to approximately 10000 watts.

19. The method as claimed in claim 1, wherein the PECVD system comprises an upper electrode and a translatable substrate holder and the chamber seasoning process includes the chamber cleaning process which further comprises:
establishing a first gap between the upper electrode and the translatable substrate holder during a first time; and
establishing a second gap between the upper electrode and the translatable substrate holder during a second time.

20. The method as claimed in claim 19, wherein the first gap is less than or equal to the second gap.

21. The method as claimed in claim 19, wherein the second gap is less than or equal to the first gap.

22. The method as claimed in claim 1, wherein the PECVD system comprises a temperature control system coupled to a substrate holder and the chamber seasoning process includes the chamber cleaning process which further comprises controlling the substrate holder temperature between approximately 0° C. and approximately 500° C.

23. The method as claimed in claim 1, wherein the PECVD system comprises a temperature control system coupled to a substrate holder and the chamber seasoning process includes the chamber pre-coating process which further comprises controlling the substrate holder temperature between approximately 0° C. and approximately 500° C.

24. The method as claimed in claim 1, wherein the PECVD system comprises a pressure control system coupled to the chamber and the chamber seasoning process includes the chamber cleaning process which further comprises controlling the chamber pressure between approximately 0.1 mTorr and approximately 100 Torr.

25. The method as claimed in claim 1, wherein the PECVD system comprises a pressure control system coupled to the chamber and the chamber seasoning process includes the chamber pre-coating process which further comprises controlling the chamber pressure between approximately 0.1 mTorr and approximately 100 Torr.

26. The method as claimed in claim 1, wherein the PECVD system comprises a temperature control system coupled to a chamber wall and the chamber seasoning process includes the chamber cleaning process which further comprises controlling the chamber wall temperature between approximately 0° C. and approximately 500° C.

27. The method as claimed in claim 1, wherein the PECVD system comprises a temperature control system coupled to a shower plate assembly and the chamber seasoning process includes the chamber cleaning process which further comprises controlling the shower plate assembly temperature between approximately 0° C. and approximately 500° C.

28. The method as claimed in claim 1, wherein the film comprises a material having a refractive index (n) ranging from approximately 1.5 to approximately 2.5 when measured at a wavelength of at least one of: 248 nm, 193 nm, and 157 nm, and an extinction coefficient (k) ranging from approximately 0.1 to approximately 0.9 when measured at a wavelength of at least one of: 248 nm, 193 nm, and 157 nm.

29. A plasma enhanced chemical vapor deposition (PECVD) system comprising:
a plasma processing chamber;
a substrate holder configured within the plasma processing chamber; and
means for performing a chamber seasoning process, wherein the chamber seasoning process comprises a chamber cleaning process, or a chamber pre-coating process, or a combination thereof, wherein the chamber cleaning process, when employed, uses a fluorine-containing gas, an oxygen-containing gas, or an inert gas, or a combination of two or more thereof, and wherein the chamber pre-coating process, when employed, uses a silicon-containing precursor, a carbon containing precursor, or an inert gas, or a combination of two or more thereof.

30. The system as claimed in claim 29 further comprising:
means for positioning a new substrate on the substrate holder in the plasma processing chamber;
means for depositing a film on the new substrate, wherein a processing gas comprising a precursor is provided to the processing chamber during the deposition process; and
means for removing the new substrate from the plasma processing chamber.

31. The system as claimed in claim 29, further comprising:
means for performing a post-process chamber cleaning process, wherein the post-process chamber cleaning process uses a fluorine-containing gas, an oxygen-containing gas, or an inert gas, or a combination of two or more thereof.

32. The system as claimed in claim 31, further comprising:
means for placing a dummy substrate on the substrate holder in the plasma processing chamber;
means for performing post process chamber cleaning process, wherein the post process chamber cleaning process uses a fluorine-containing gas, an oxygen-containing gas, or an inert gas, or a combination of two or more thereof; and
means for removing the dummy substrate from the substrate holder after post process chamber cleaning process.

33. The system as claimed in claim 29, wherein the film comprises a Tunable Etch Resistant ARC (TERA) material.

34. The system as claimed in claim 29, further comprising:
means for placing a dummy substrate on the substrate holder in the plasma processing chamber; and
means for removing the dummy substrate from the substrate holder after chamber seasoning process.
